(19) United States
(12) Patent Application Publication
(10) Pub. No.: US 2024/0295823 A1
(43) Pub. Date: Sep. 5, 2024

(54) METHOD FOR MANUFACTURING ELECTRONIC DEVICE

(71) Applicant: Innolux Corporation, Miaoli County (TW)

(72) Inventors: Chun-Yuan Chuang, Miaoli County (TW); Ming-Chih Chen, Miaoli County (TW); Jean Huang, Miaoli County (TW); Wei-Jen Wang, Miaoli County (TW); Tao-Lung Cheng, Miaoli County (TW)

(73) Assignee: Innolux Corporation, Miaoli County (TW)

(21) Appl. No.: 18/662,967

(22) Filed: May 13, 2024

Related U.S. Application Data
(63) Continuation of application No. 16/908,658, filed on Jun. 22, 2020.
(60) Provisional application No. 62/893,195, filed on Aug. 29, 2019.

(51) Int. Cl. G03F 7/40; G03F 7/16; H01L 21/027; H01L 21/308

(52) U.S. Cl. CPC G03F 7/40; G03F 7/168; H01L 21/0274; H01L 21/3086

(57) ABSTRACT

A method for manufacturing an electronic device is provided. In the method for manufacturing an electronic device, a substrate is provided, a device layer is disposed on the substrate, and a photoresist layer is disposed on the device layer. Next, a photo mask is disposed on the photoresist layer, and a light source is used to firstly illuminate the photo mask to form a first exposure region. After that, a relative movement is made between the substrate and the photo mask, and the light source is used to secondly illuminate the photo mask to form a second exposure region, wherein the first exposure region partially overlaps the second exposure region. Afterwards, a pattern is developed on the substrate, the device layer is etched using a patterned photoresist layer as an etching mask, and then the patterned photoresist layer is removed.

### CROSS-REFERENCE TO RELATED APPLICATION

This is a continuation application of U.S. application Ser. No. 16/908,658, filed on Jun. 22, 2020, which claims the priority benefit of U.S. provisional application Ser. No. 62/893,195, filed on Aug. 29, 2019. The entirety of each of the above-mentioned patent applications is hereby incorporated by reference herein and made a part of this specification.

### BACKGROUND

### Technical Field

The disclosure relates to a method for manufacturing an electronic device, and more particularly to a method for manufacturing an electronic device with narrow line widths.

### Description of Related Art

Currently, an electronic device with narrow line widths (e.g. less than or equal to 1 μm) can be achieved by a two-mask method (i.e. using two different photo masks to develop patterns on a same region). However, the equipments used in the two-mask method are expensive, and it results in the high cost. Therefore, reducing the cost for manufacturing an electronic device with narrow line widths is a topic to be studied currently.

### SUMMARY

The disclosure provides a method for manufacturing an electronic device, the method is able to lower the cost for manufacturing an electronic device with narrow line widths.

According to an embodiment of the disclosure, in the method for manufacturing an electronic device, a substrate is provided, a device layer is disposed on the substrate, and a photoresist layer is disposed on the device layer. Next, a photo mask is disposed on the photoresist layer, and a light source is used to firstly illuminate the photo mask to form a first exposure region. After that, a relative movement is made between the substrate and the photo mask, and the light source is used to secondly illuminate the photo mask to form a second exposure region, wherein the first exposure region partially overlaps the second exposure region. Afterwards, a developing process is performed to form a patterned photoresist layer. An etching process is then performed to form a patterned device layer, wherein the device layer is etched to be a patterned device layer by using the patterned photoresist layer as an etching mask, and then the patterned photoresist layer is removed.

In order to make the above features and advantages of the disclosure more obvious, the following embodiment is described in detail with reference to the accompanying drawings.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1H are schematic cross-sectional views of a method for manufacturing an electronic device according to an embodiment of the disclosure.

FIG. 2 is a flow chart of the manufacturing process according to an embodiment of the disclosure.

### DESCRIPTION OF THE EMBODIMENTS

The disclosure can be understood with reference to the following exemplary embodiments and the accompanying drawings. For easy understanding and simplicity of drawings, some of the drawings in the disclosure depict only a portion of the electronic device, and specific components in the drawings are not drawn according to actual scales.

In the drawings, common characteristics of the methods, structures and/or materials used in specific exemplary embodiments are shown. However, the drawings are not limited to the structures or features of the following embodiments and the drawings should not be interpreted to define or limit the scopes or the properties of the descriptions in the exemplary embodiments. For instance, the relative dimension, thickness, and location of each film layer, region, and/or structure may be reduced or enlarged for clarity.

Certain terms are used throughout the description and the claims to refer to particular elements. People skilled in the pertinent art shall appreciate that electronic device manufacturers may use different names to denote the same element. The disclosure does not aim at distinguishing the elements with the same function but different names.

In the description and claims, the words “having,” “including,” and “comprising” are open-ended and therefore should be interpreted as “including but not limited to”. Moreover, “first”, “second”, etc. mentioned in the specification and the claims are merely used to name the discrete elements or to differentiate different ranges or embodiments and therefore should not be regarded as limiting the upper or lower bound of the number of the components/devices and should not be used to limit the manufacturing sequence of components.

The directional terminologies mentioned in the detailed description, such as “top,” “bottom,” “front,” “back,” “left,” or “right”, etc., are used as a reference to the orientation of the drawings being described. Accordingly, the drawings and descriptions will be regarded as being illustrative in nature but not as being restrictive.

It should be understood that when an element or a film layer is referred to as being disposed “on” another element or another film layer or “connecting/bonding” another element or another film layer, the element or the film layer may be directly located on the other element or film layer or directly connected/bonded to the other element or film layer, or there may be an intervening element or film layer between the two elements (indirect connection/bonding). By contrast, when the element or the film layer is referred to as being “directly on” or “directly connected/bonded” to another element or another film layer, there is no intervening element nor film layer between the two elements. In addition, connecting or bonding two elements to each other may indicate both elements are fixed or at least one of the elements is movable.

The terms “about”, “approximately”, or “substantially”, used herein are generally meant to fall within a nearby range of 20%, or 10%, or 5%, or 3%, or 2%, or 1%, or 0.5% of a given value.

The electronic device of the disclosure may include, for example, a display device, an antenna device, a sensing device, a touch display device, a curved display device, a free shape display device, a foldable electronic device, a flexible electronic device, a tiled electronic device or combination thereof. However, the disclosure is not limited thereto. The electronic device may include, for example, light emitting diodes, liquid crystals, quantum dots, fluorescent materials, other suitable display media, or a combination thereof, but is not limited thereto. The light emitting diode may include, for example, an organic light emitting diode (OLED), an inorganic light emitting diode (LED), a mini light emitting diode (mini LED), a micro light emitting diode (micro LED), a quantum dot light emitting diode (QLED or QDLED), other suitable materials or a combination thereof, but is not limited thereto. The antenna device may be, for example, a liquid crystal antenna, but is not limited thereto. It should be noted that a tilted electronic device can be any of the aforementioned combinations, but is not limited thereto. In addition, the appearance of the tilted electronic device can be rectangular, circular, polygonal, a shape with curved edges, or other suitable shapes. The electronic device may have a peripheral system, such as a driving system, a control system, a light source system, a shelf system, etc., to support a display device or an antenna device.

In the following embodiments, the same or similar elements will be given the same or similar reference numerals, and the description thereof will be omitted. In addition, the features provided in different embodiments may be arbitrarily combined and applied without departing from the spirit of the disclosure, and the simple equivalent changes and modifications made in the descriptions or claims are still within the scope of the disclosure.

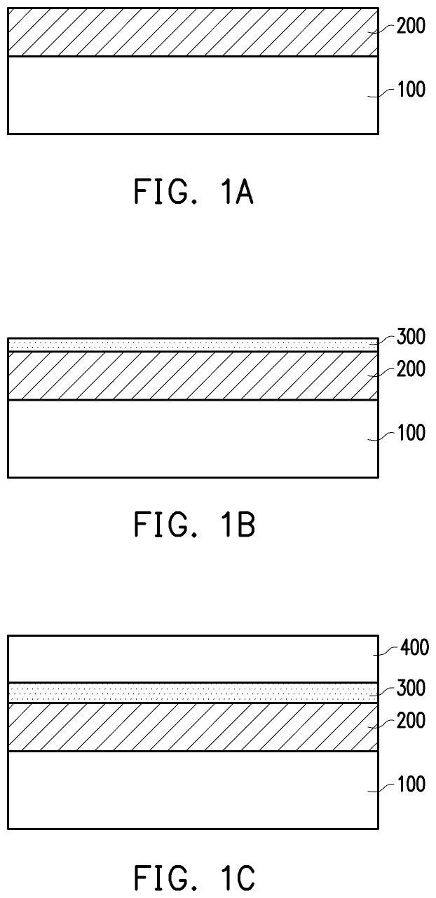

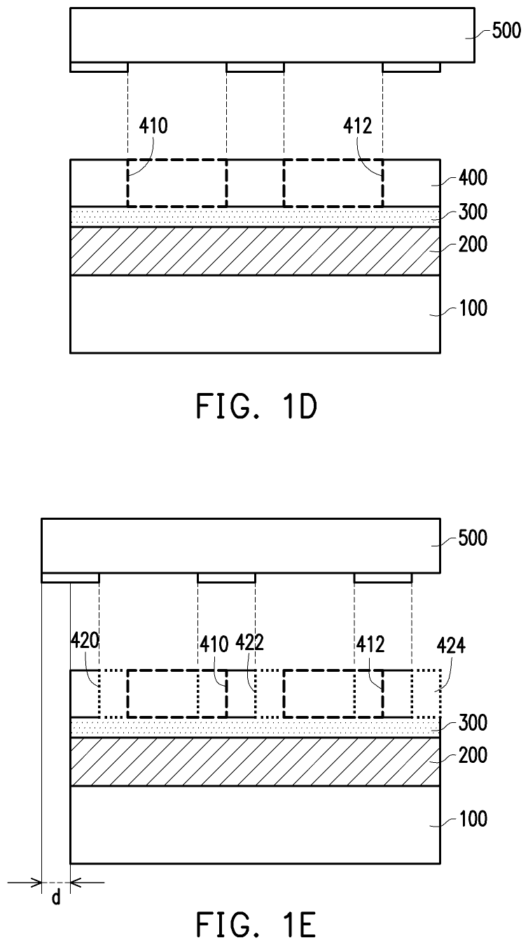

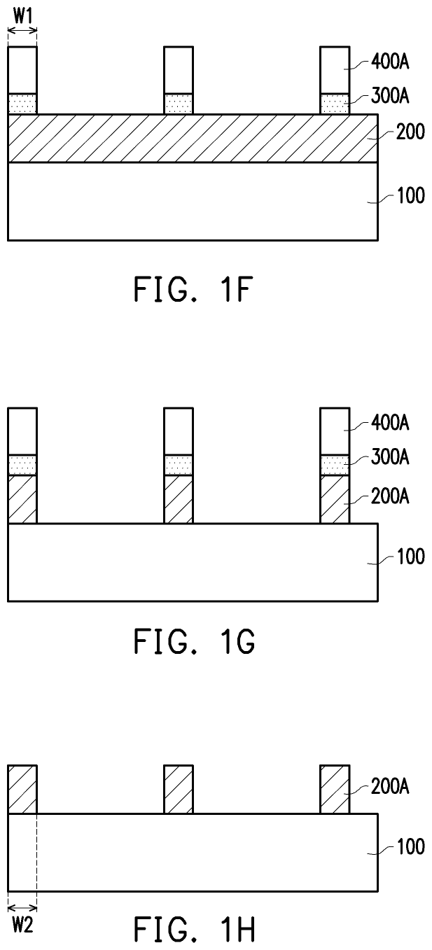

FIG. 1A to FIG. 1H are schematic cross-sectional views of a method for manufacturing an electronic device according to an embodiment of the disclosure.

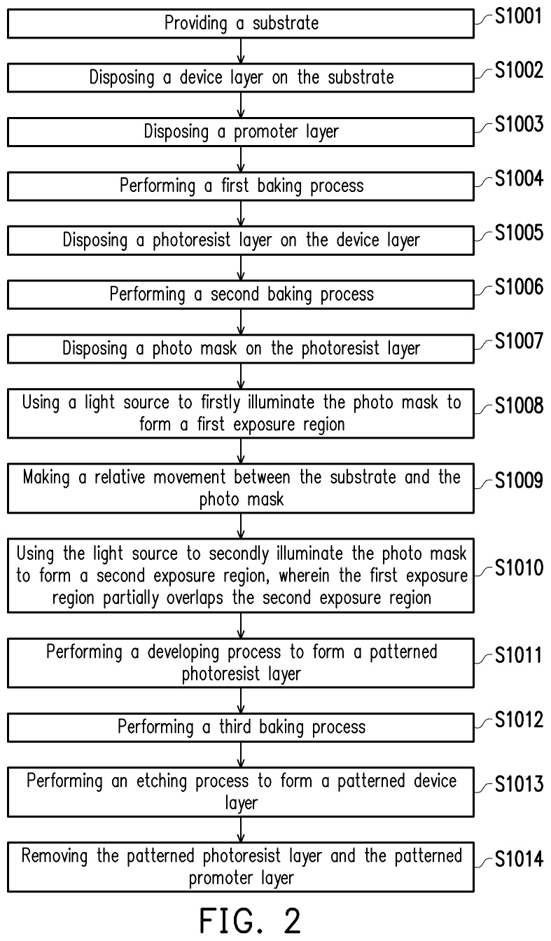

FIG. 2 is a flow chart of the manufacturing process according to an embodiment of the disclosure. The manufacturing process can include step S1001 to step S1014, but the disclosure is not limited thereto. Any reasonable technology modification and extra manufacturing step is applicable. Step S1001 to step S1014 are illustrated below:
step S1001: providing a substrate;
step S1002: disposing a device layer on the substrate;
step S1003: disposing a promoter layer;
step S1004: performing a first baking process;
step S1005: disposing a photoresist layer on the device layer;
step S1006: performing a second baking process;
step S1007: disposing a photo mask on the photoresist layer;
step S1008: using a light source to firstly illuminate the photo mask to form a first exposure region;
step S1009: making a relative movement between the substrate and the photo mask;
step S1010: using the light source to secondly illuminate the photo mask to form a second exposure region, wherein the first exposure region partially overlaps the second exposure region;
step S1011: performing a developing process to form a patterned photoresist layer;
step S1012: performing a third baking process;
step S1013: performing an etching process to form a patterned device layer; and
step S1014: removing the patterned photoresist layer and the patterned promoter layer.

The details of step S1001 to step S1014 will be illustrated in the following paragraphs.

With reference to FIG. 1A and FIG. 2, a substrate 100 is provided in step S1001, and a device layer 200 is disposed on the substrate 100 in step S1002. The substrate 100 may be a glass substrate or a flexible substrate, and a material of the flexible substrate may include polyimide, but the disclosure is not limited thereto. A material of the device layer 200 may include a metal or other electrical conductive material, but the disclosure is not limited thereto.

With reference to FIG. 1B and FIG. 2, in step S1003, a promoter layer 300 is disposed on the device layer 200, and a thickness of the promoter layer 300 is less than 100 Å, but the disclosure is not limited thereto. In step S1004, in order to dry the promoter layer 300, after disposing the promoter layer 300 on the device layer 200, a first baking process is performed. To be more specific, the first baking process is performed between disposing the promoter layer 300 and disposing the photoresist layer 400 (as shown in FIG. 1C). More particularly, a first temperature range of the first baking process may be 150° C. to 210° C. (150° C.≤first temperature range≤210° C.) or 170° C. to 200° C. (170° C.≤first temperature range≤200° C.), and a first time range of the first baking process may be 15 seconds to 45 seconds (15 seconds≤first time range≤45 seconds) or 20 seconds to 35 seconds (20 seconds≤first time range≤35 seconds), but the disclosure is not limited thereto.

With reference to FIG. 1C and FIG. 2, in step S1005, a photoresist layer 400 is disposed on the promoter layer 300, and the photoresist layer 400 may include a chemically amplified photoresist, but the disclosure is not limited thereto. In other words, the promoter layer 300 is disposed between the device layer 200 and the photoresist layer 400. The promoter layer 300 is able to enhance the adhesion of the photoresist layer 400 to the device layer 200, and the peeling of photoresist layer 400 may be reduced by the promoter layer 300. After disposing the photoresist layer 400, in step S1006, a second baking process is performed. To be more specific, the second baking process is performed between disposing the photoresist layer 400 and disposing the photo mask 500 (as shown in FIG. 1D). More particularly, a second temperature range of the second baking process may be 80° C. to 140° C. (80° C.≤second temperature range≤140° C.) or 90° C. to 120° C. (90° C.≤second temperature range≤120° C.), and a second time range of the second baking process may be 25 seconds to 55 seconds (25 seconds≤second time range≤55 seconds) or 30 seconds to 45 seconds (30 seconds≤second time range≤45 seconds), but the disclosure is not limited thereto. A suitable time range or temperature range in the second baking process can enhance the property of the photoresist layer, and the profile of a patterned photoresist layer (obtained in later step S1011) can be a substantially rectangular shape rather than a trapezoid shape in a cross sectional view.

With reference to FIG. 1D and FIG. 2, in step S1007, a photo mask 500 is disposed on the photoresist layer 400, and then in step S1008, a light source (not shown) is used to firstly illuminate the photo mask 500 to form first exposure regions 410 and 412. More particularly, a light emitted from the light source may have a wavelength in a range from 350 nm to 460 nm (350 nm≤wavelength≤460 nm), but the disclosure is not limited thereto. It should be noted that the photo mask 500 does not directly contact the photoresist layer 400, in other words, there is a distance between photo mask 500 and the photoresist layer 400.

With reference to FIG. 1E and FIG. 2, in step S1009, a relative movement is made between the substrate 100 and the photo mask 500, wherein a path length d of the relative movement between the substrate 100 and the photo mask 500 may be in a range from 0.05 μm to 5 μm (0.05 μm≤path length≤5 μm), but the disclosure is not limited thereto. In a top view, an end of a corner of the photo mask can be projected onto the substrate at a first point when firstly illuminating the photo mask 500, and the same end can be projected onto the substrate at a second point when secondly illuminating the photo mask 500. The path length d can be defined as a distance between the first point and the second point. In the embodiment, the relative movement may be made by moving the substrate 100 without moving the photo mask 500, but the disclosure is not limited thereto. In step S1010, after making a relative movement between the substrate 100 and the photo mask 500, the light source (not shown) is used to secondly illuminate the photo mask 500 to form second exposure regions 420, 422 and 424, wherein the first exposure regions 410 and 412 partially overlaps the second exposure regions 420 and 422. More particularly, the light emitted from the light source may have a wavelength in a range from 350 nm to 460 nm (350 nm≤wavelength≤460 nm).

With reference to FIG. 1E, FIG. 1F and FIG. 2, in step S1011, a developing process is performed to form a patterned photoresist layer 400A and a patterned promoter layer 300A. In other words, portions of the photoresist layer 400 and the promoter layer 300 are removed during the developing process, and a portion of the device layer 200 is exposed. In step S1012, after the developing process, a third baking process is performed. A third temperature range of the third baking process may be 80° C. to 140° C. (80° C.≤third temperature range≤140° C.), or 100° C. to 120° C. (100° C.≤third temperature range≤120° C.), and a third time range of the third baking process may be 35 seconds to 65 seconds (35 seconds≤third time range≤65 seconds) or 40 seconds to 55 seconds (40 seconds≤third time range≤55 seconds), but the disclosure is not limited thereto. A suitable time range or temperature range in the third baking process can enhance the property of the patterned photoresist layer, and the profile of a patterned photoresist layer can be a substantially rectangular shape rather than a trapezoid shape in a cross sectional view. A portion of the patterned photoresist layer 400A has a line width W1, and the line width W1 may be equal to or less than 1 μm (0<W1≤1 μm), but the disclosure is not limited thereto. It should be noted that the line width W1 is a width of a portion of a patterned photoresist layer 400A in a cross sectional view. To be more specific, the line width W1 is a maximum line width measured in a direction perpendicular to an extension direction of the portion of the patterned photoresist layer 400A in the cross sectional view.

With reference to FIG. 1F, FIG. 1G and FIG. 2, in step S1013, an etching process is performed, wherein the device layer 200 is etched by using the patterned photoresist layer 400A as an etching mask, and a patterned device layer 200A is formed. With reference to FIG. 1H and FIG. 2, in step S1014, the patterned photoresist layer 400A and the patterned promoter layer 300A are removed. In the embodiment, the patterned device layer 200A has a line width W2 equal to or less than 1 μm (0<W2≤1 μm) after the etching process, but the disclosure is not limited thereto. Similar to the line width W1, the line width W2 is a maximum line width measured in a direction perpendicular to an extension direction of the portion of the patterned device layer 200A in a cross sectional view. In some embodiments, the line width W2 of the patterned device layer 200A is equal to or less than the line width W1 of the photoresist layer, but the disclosure is not limited thereto.

In summary, the method for manufacturing the electronic device of the disclosure includes making a relative movement between the substrate and the photo mask after the first illumination which forms a first exposure region and before the second illumination which forms a second exposure region such that the first exposure region partially overlaps the second exposure region. Therefore, an electronic device with narrow line widths can be achieved by the method for manufacturing the electronic device of the disclosure. Also, the method for manufacturing the electronic device of the disclosure uses simply one mask or cheaper equipments instead of the traditional two-mask method, and the cost can be lower.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

The above embodiments merely serve to explain but not restrict the technical schemes provided in the disclosure. Although detailed descriptions are provided in detail with reference to the above embodiments, people having ordinary skill in the pertinent art should understand that the technical schemes described in the foregoing embodiments may be modified, or some or all of the technical features above may be equivalently replaced; these modifications or replacement may be provided without departing from the scope provided in one or more embodiments in the disclosure.

Although the embodiments and the advantages have been disclosed above, it should be understood that people having ordinary skill in the pertinent art may make changes, substitutions, and refinements without departing from the spirit and scope of the disclosure. In addition, the scope of protection provided in the disclosure is not limited to the processes, machine, fabrications, compositions of substances, devices, methods, and steps provided in one or more embodiments described herein. People having ordinary skill in the pertinent art are able to understand the processes, machine, fabrications, compositions of substances, devices, methods, and steps provided in one or more embodiments developed at present or in the future, as long as the same function can be performed or the same result can be achieved according to the embodiments described in the disclosure. Accordingly, the scope of protection of the disclosure includes the above-mentioned processes, machine, fabrications, and compositions of substances, devices, methods, and steps. In addition, each claim constitutes an individual embodiment, and the scope of the disclosure also includes any combination of the various claims and embodiments. The scope of protection of the disclosure is subject to what is defined in the appended claims. Any embodiment or claim of the disclosure is not required to achieve all the objectives, advantages, and features disclosed herein.

What is claimed is:

1. A method for manufacturing an electronic device, comprising:
providing a substrate;
disposing a device layer on the substrate;
disposing a promoter layer on the device layer;
after disposing the promoter layer, performing a first baking process;
disposing a photoresist layer on the promoter layer;
after disposing the photoresist layer, performing a second baking process, wherein a temperature range of the first baking process does not overlap a temperature range of the second baking process;
disposing a photo mask on the photoresist layer;
using a light source to firstly illuminate the photo mask to form a first exposure region;
making a relative horizontal movement between the substrate and the photo mask;
using the light source to secondly illuminate the photo mask to form a second exposure region, wherein the first exposure region partially overlaps the second exposure region;
performing a developing process to form a patterned photoresist layer;
after performing the developing process, performing a third baking process; and
performing an etching process to form a patterned device layer.

2. The method of claim 1, wherein a patterned promoter layer is formed in the developing process, and the method further comprises removing the patterned photoresist layer and the patterned promoter layer after performing the etching process.

3. The method of claim 1, wherein a thickness of the promoter layer is less than 100 Å.

4. The method of claim 1, wherein the temperature range of the first baking process is 150° C. to 210° C.

5. The method of claim 1, wherein a time range of the first baking process is 15 seconds to 45 seconds.

6. The method of claim 1, wherein a material of the device layer comprises a metal or other electrical conductive material.

7. The method of claim 1, wherein the temperature range of the second baking process is 80° C. to 140° C.

8. The method of claim 1, wherein a time range of the second baking process is 25 seconds to 55 seconds.

9. The method of claim 1, wherein a temperature range of the third baking process is 80° C. to 140° C.

10. The method of claim 1, wherein a time range of the third baking process is 35 seconds to 65 seconds.

11. The method of claim 1, wherein a portion of the patterned photoresist layer has a line width, and the line width is equal to or less than 1 μm.

12. The method of claim 1, wherein a portion of the patterned device layer has a line width, and the line width is equal to or less than 1 μm.

13. The method of claim 1, wherein a light emitted from the light source has a wavelength in a range from 350 nm to 460 nm.

14. The method of claim 1, wherein the photoresist layer comprises a chemically amplified photoresist.

15. The method of claim 1, wherein a path length of the relative movement between the substrate and the photo mask is in a range from 0.05 μm to 5 μm.
